(19) United States
(12) Patent Application Publication
(10) Pub. No.: US 2014/0353780 A1
(43) Pub. Date: Dec. 4, 2014

(54) DETECTION STRUCTURE FOR A MEMS ACOUSTIC TRANSDUCER WITH IMPROVED ROBUSTNESS TO DEFORMATION

(71) Applicant: STMicroelectronics S.r.l., Agrate Brianza (IT)

(72) Inventors: Matteo Perletti, Vaprio d'Adda (IT); Sebastiano Conti, Mistretta (IT); Roberto Carminati, Piancogno (IT); Marcella Capezzuto, Sedriano (IT)

(73) Assignee: STMicroelectronics S.r.l., Agrate Brianza (IT)

(21) Appl. No.: 14/288,106

(22) Filed: May 27, 2014

(30) Foreign Application Priority Data
May 30, 2013 (IT) TO2013A000441

(51) Int. Cl. B81B 3/00; B81C 1/00

(52) U.S. Cl. CPC B81B 3/0051; B81B 3/0021; B81C 1/00158; B81B 2201/0257
USPC 257/416; 438/53

(57) ABSTRACT

A micromechanical structure for a MEMS capacitive acoustic transducer, has: a substrate of semiconductor material; a rigid electrode, at least in part of conductive material, coupled to the substrate; a membrane, at least in part of conductive material, facing the rigid electrode and coupled to the substrate, which undergoes deformation in the presence of incident acoustic pressure waves and is arranged between the substrate and the rigid electrode and has a first surface and a second surface, in fluid communication, respectively, with a first chamber and a second chamber, the first chamber being delimited at least in part by a first wall portion and by a second wall portion formed by the substrate, and the second chamber being delimited at least in part by the rigid electrode; and a stopper element, connected between the first and second wall portions for limiting the deformations of the membrane. At least one electrode-anchorage element couples the rigid electrode to the stopper element.

### BACKGROUND

1. Technical Field

The present disclosure relates to a detection structure for a MEMS (Micro-Electro-Mechanical Systems) acoustic transducer, in particular a microphone of a capacitive type. The detection structure has an improved robustness to deformation.

2. Description of the Related Art

As is known, a MEMS acoustic transducer, of a capacitive type, generally comprises a mobile electrode, provided as a diaphragm or a membrane, set facing a rigid electrode so as to provide the plates of a detection capacitor. The mobile electrode is generally anchored, by means of a perimetral portion, to a substrate, whereas a central portion is free to move or bend, in particular in response to acoustic pressure waves impinging on a surface thereof (or in general in response to external stresses). The mobile electrode and the rigid electrode provide a detection capacitor, and bending of the membrane that constitutes the mobile electrode causes a variation of capacitance of this detection capacitor. During operation, the capacitance variation is converted, by suitable processing electronics, into an electrical signal, which is supplied as an output signal of the MEMS acoustic transducer.

A MEMS acoustic transducer of a known type is, for example, described in the patent application No. US 2010/0158279 A1 (to which reference is made herein), filed in the name of the present Applicant.

FIG. 1 is a schematic illustration, provided by way of example, of a portion of the micromechanical detection structure of the acoustic transducer, designated as a whole by 1.

The detection structure 1 comprises a substrate 2 made of semiconductor material, for example silicon, and a mobile membrane (or diaphragm) 3. The membrane 3 is made at least in part of conductive material and faces a fixed electrode or rigid plate 4, generally known as “back plate”, which is rigid, that is, at least if compared with the membrane 2, which is, instead, flexible and undergoes deformation as a function of the incident acoustic pressure waves.

The membrane 3 is anchored to the substrate 2 by means of membrane anchorages 5, formed by protuberances of the same membrane 3, which extend, starting from peripheral regions of the membrane 3, towards the substrate 2.

For example, the membrane 3 has, in plan view, i.e., in a horizontal plane xy of main extension, a generally square shape, and the membrane anchorages 5, which are four in number, are set at the vertices of the square.

The membrane anchorages 5 suspend the membrane 3 above the substrate 2, at a certain distance therefrom, forming a gap. The value of this distance is the result of a compromise between the linearity of response at low frequencies and the noise of the acoustic transducer.

The rigid plate 4 is formed by a first plate layer 4a, made of conductive material and facing the membrane 3, and a second plate layer 4b, made of insulating material.

The first plate layer 4a forms, together with the membrane 3, the detection capacitor of the micromechanical structure 1.

The second plate layer 4b is arranged on the first plate layer 4a, except for portions (not illustrated) in which it extends through the first plate layer 4a so as to form protuberances (here not illustrated) of the rigid plate 4, which extend towards the underlying membrane 3 and have the function of preventing adhesion of the membrane 3 to the rigid plate 4, as well as of limiting the extent of the oscillations of the membrane 3 following its deformation.

For example, the thickness of the membrane 3 is in the range of 0.3-1.5 μm, e.g., 0.7 μm, the thickness of the first plate layer 4a is in the range of 0.5-2 μm, e.g., 0.9 μm, and the thickness of the second plate layer 4b is in the range of 0.7-2 μm, e.g., 1.2 μm.

The rigid plate 4 has a plurality of holes 7, which extend through the first and second plate layers 4a, 4b, have, for example, a circular cross section, and perform the function of favoring, during the manufacturing steps, removal of the underlying sacrificial layers. Holes 7 are, for example, arranged to form a lattice, in the horizontal plane xy. Moreover, during operation, holes 7 enable free circulation of air between the rigid plate 4 and the membrane 3, in effect rendering the same rigid plate 4 acoustically transparent. Holes 7 thus define an acoustic port, for enabling the acoustic pressure waves to reach the membrane 3 and deform it.

The rigid plate 4 is anchored to the substrate 2 by means of first plate anchorages 8, connected to peripheral regions of the same rigid plate 4 and coupled to the substrate 2, externally with respect to the membrane anchorages 5.

In particular, the first plate anchorages 8 are formed by vertical pillars (i.e., extending in a vertical direction z, orthogonal to the horizontal plane xy and to the substrate 2), made, at least in part, of the same material as the rigid plate 4 (for example, as the second plate layer 4b), and hence forming a single piece with the same rigid plate 4.

Moreover, the membrane 3 is suspended over and directly faces a first cavity 9a, formed inside, and through, the substrate 2, defined by a trench starting from a back surface 2b of the substrate 2, which is opposite to a front surface 2a thereof, on which the membrane anchorages 5 and the first plate anchorages 8 rest. The first cavity 9a hence defines a through opening that extends between the front surface 2a and the back surface 2b of the substrate 2; in particular, the front surface 2a and the back surface 2b are parallel to the horizontal plane xy.

The first cavity 9a is also known as “back chamber” in the case where the acoustic pressure waves impinge first on the rigid plate 4 and then on the membrane 3. In this case, the front chamber is formed by a second cavity 9b, which is delimited at the top and at the bottom, respectively, by the first plate layer 4a of the rigid plate 4 and by the membrane 3.

Alternatively, it is in any case possible for the pressure waves to reach the membrane 3 through the first cavity 9a, which in this case performs the function of acoustic access port, and, hence, of front chamber.

In greater detail, the membrane 3 has a first surface 3a and a second surface 3b, which are opposite to one another and face, respectively, the first and the second cavities 9a, 9b, hence being in fluid communication with a respective one between the back and front chambers of the acoustic transducer.

Moreover, the first cavity 9a is formed by two cavity portions 9a′, 9a″: a first cavity portion 9a′ is set at the front surface 2a of the substrate 2 and has a first extension in the horizontal plane xy; the second cavity portion 9a″ is set at the back surface 2b of the substrate 2 and has a second extension in the horizontal plane xy, greater than the first extension.

In particular, the first cavity portion 9a′ is defined, at least in part, between a first wall portion W₁ and a second wall portion W₂ of a front portion of the substrate 2, set at the front surface 2a, whereas the second cavity portion 9a″ is defined, at least in part, between a respective first wall portion L₁ and a respective second wall portion L₂ of a back portion of the same substrate 2, set at the back surface 2b.

As represented schematically in FIG. 2, both the first cavity portion 9a′ and the second cavity portion 9a″ have, for example, a parallelepipedal shape, having a square or rectangular shape in a cross section parallel to the horizontal plane xy. Consequently, the first cavity portion 9a′ is delimited, not only by the first and second wall portions W₁, W₂, but also by a third wall portion W₃ and a fourth wall portion W₄ (in FIG. 2, the third wall portion W₃ is illustrated, in addition to the aforesaid first wall portion W₁), and the second cavity portion 9a″ is delimited, not only by the first and second respective wall portions L₁, L₂, but also by a respective third wall portion L₃ and fourth wall portion L₄ (FIG. 2 illustrates the respective third wall portion L₃).

The membrane 3 is arranged above the first cavity portion 9a′, overlying it entirely (i.e., having a greater extension in the horizontal plane xy), and the membrane anchorages 5 are set on the substrate 2, laterally with respect to the same first cavity portion 9a′.

In a known manner, the sensitivity of the acoustic transducer is a function of the mechanical characteristics of the membrane 3, as well as of the assembly of the membrane 3 and of the rigid plate 4.

Moreover, the performance of the acoustic transducer depends upon the volume of the back chamber and the volume of the front chamber. In particular, the volume of the front chamber determines the upper resonance frequency of the acoustic transducer, and hence its performance at high frequencies. In general, in fact, the smaller the volume of the front chamber, the higher the upper cut-off frequency of the acoustic transducer.

Moreover, a large volume of the back chamber improves the frequency response and the sensitivity of the acoustic transducer (this is a reason for the presence of the second cavity portion 9a″ in the substrate 2, having a greater extension in the horizontal plane xy).

The present Applicant has found that the detection structure 1 described above is affected by certain drawbacks, linked in particular to the mechanical robustness to the deformations to which it may be subject during operation.

As previously mentioned, during its operation, the membrane 3 may undergo vertical deformation in the direction of the rigid plate 4, or, alternatively, in the direction of the substrate 2. The extent of this deformation of the membrane 3 is evidently greater near its central portion, which is not constrained, whereas it is smaller, even zero, around its peripheral portion, constrained at the membrane anchorages 5.

In particular, the extent of the displacements of the membrane 3 may be such as to cause mechanical failure thereof. This may, for example, occur following upon impacts undergone by the electronic device in which the acoustic transducer is integrated, or else in a free-fall condition of the same electronic device. A free-fall condition may even be simulated during a testing procedure for the MEMS acoustic transducer.

In order to limit the extent of the displacements of the membrane 3 in the direction of the rigid plate 4, the structure described envisages the presence of the same rigid plate 4 and of the associated protuberances, operating as top stopper elements.

The deformations in the direction of the substrate 2 are, instead, limited by an appropriate sizing of the first cavity portion 9a′ and by the positioning of the membrane anchorages 5. In fact, in the presence of deformations of considerable extent, peripheral parts of the membrane 3 abut on the front portion of the substrate 2, limiting the deformation of the membrane 3. In other words, the membrane 3 is not free to undergo deformation inside the first cavity portion 9a′, without coming into contact with the front portion of the substrate 2 that laterally defines the same first cavity portion 9a′.

However, these solutions have proven satisfactory typically only in the case of deformations of small amplitude. In fact, in the case of considerable stresses, the central part of the membrane 3 is in any case subject to marked deformations, which may lead to breaking.

Moreover, also the rigid plate 4 may be subject to damage, and possibly breaking, due to the impact of the membrane 3 against the protuberances of the same rigid plate 4. In particular, great mechanical stresses, and even breaking, may occur at the peripheral portions of the rigid plate 4, near the first plate anchorages 8, on account of the deformations originating at the center of the same rigid plate 4 as a result of impact with the membrane 3.

A solution proposed in order to limit this problem envisages thickening of the rigid plate 4, but this is at the expense of the economy of the manufacturing process and of the resulting dimensions of the acoustic transducer. Also this solution is hence not altogether satisfactory.

### BRIEF SUMMARY

According to one or more embodiments of the present disclosure, a detection structure for a MEMS acoustic transducer is provided. In one embodiment there is provided a micromechanical structure for a MEMS capacitive acoustic transducer, comprising a semiconductor substrate and a rigid electrode coupled to said substrate. The structure further includes a membrane having a first surface and a second surface. The second surface faces the rigid electrode. The membrane is coupled to said substrate and configured to deform in response to acoustic pressure. The membrane may be arranged between the substrate and the rigid electrode. The structure further includes a first chamber and a second chamber. The first chamber is delimited at least in part by a first wall portion and a second wall portion formed at least in part by the substrate and the first surface of the membrane. The second chamber is delimited at least in part by the rigid electrode and the second surface of the membrane. The structure further includes a stopper element coupled between said first and second wall portions. The stopper element is configured to limit deformations of the membrane above a threshold. The structure includes an electrode-anchorage element that couples said rigid electrode to said stopper element.

### BRIEF DESCRIPTION OF THE SEVERAL VIEWS OF THE DRAWINGS

For a better understanding of the present disclosure, preferred embodiments thereof are now described, purely by way of non-limiting example and with reference to the attached drawings, wherein:

FIG. 1 is a schematic cross-sectional view of a portion of a micromechanical detection structure of a MEMS acoustic transducer of a known type;

FIG. 2 is a schematic perspective view of a portion of the micromechanical detection structure of FIG. 1;

FIG. 3 is a schematic cross-sectional view of a portion of a micromechanical detection structure of a MEMS acoustic transducer, according to one embodiment of the present disclosure;

FIG. 4 is a schematic perspective view of a portion of the micromechanical detection structure of FIG. 3;

FIG. 5 is a further schematic perspective view of a portion of the micromechanical detection structure of FIG. 3;

FIG. 6 is a block diagram of an electronic device including the MEMS acoustic transducer; and

FIGS. 7a and 7b are schematic plan views of different embodiments of the micromechanical detection structure.

### DETAILED DESCRIPTION

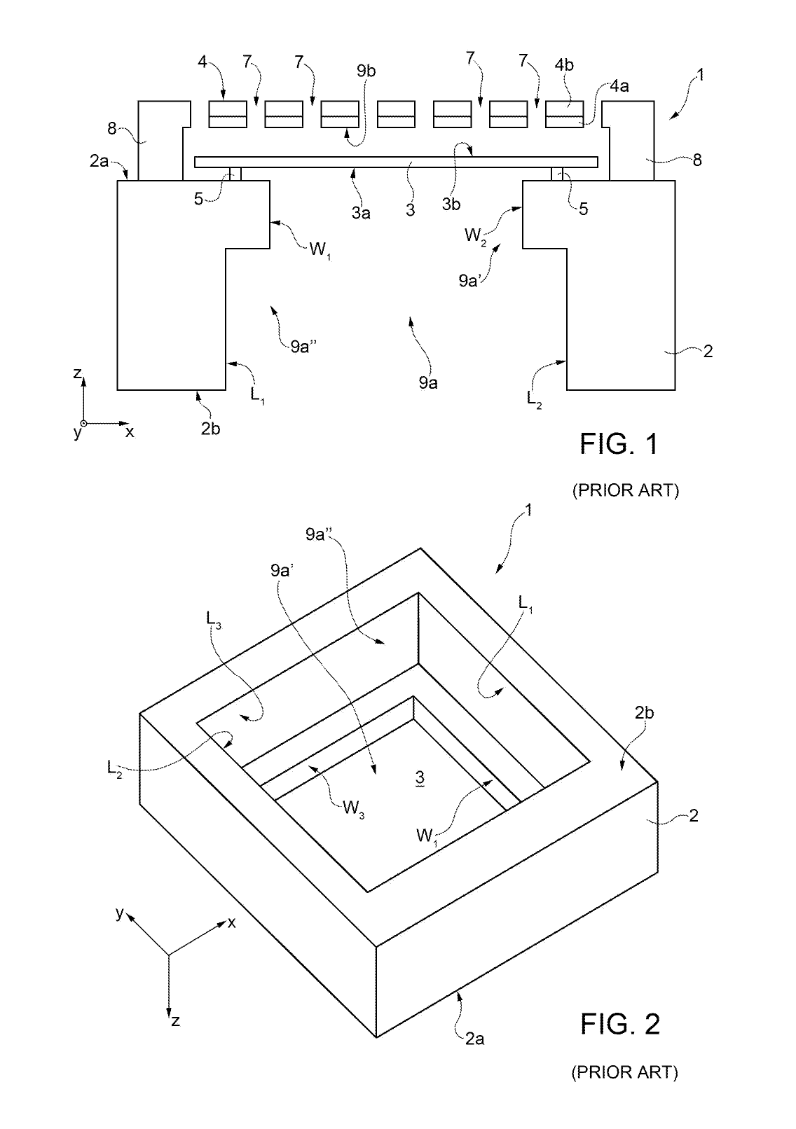

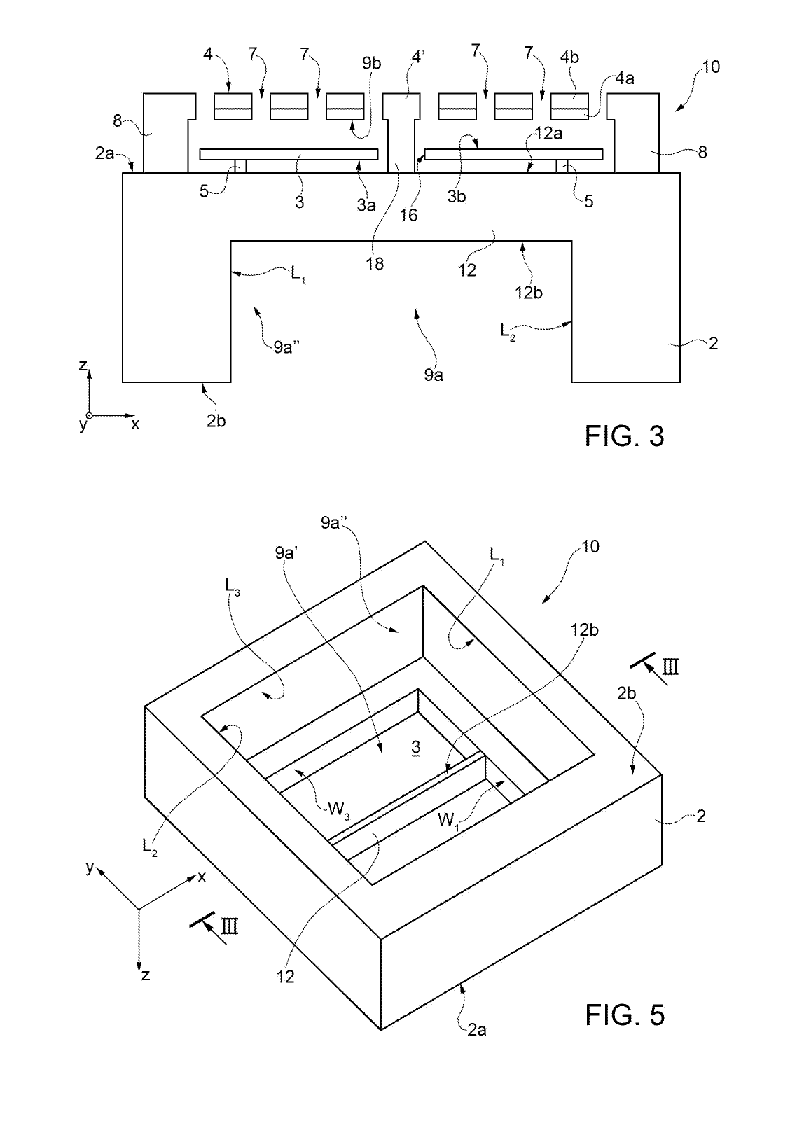

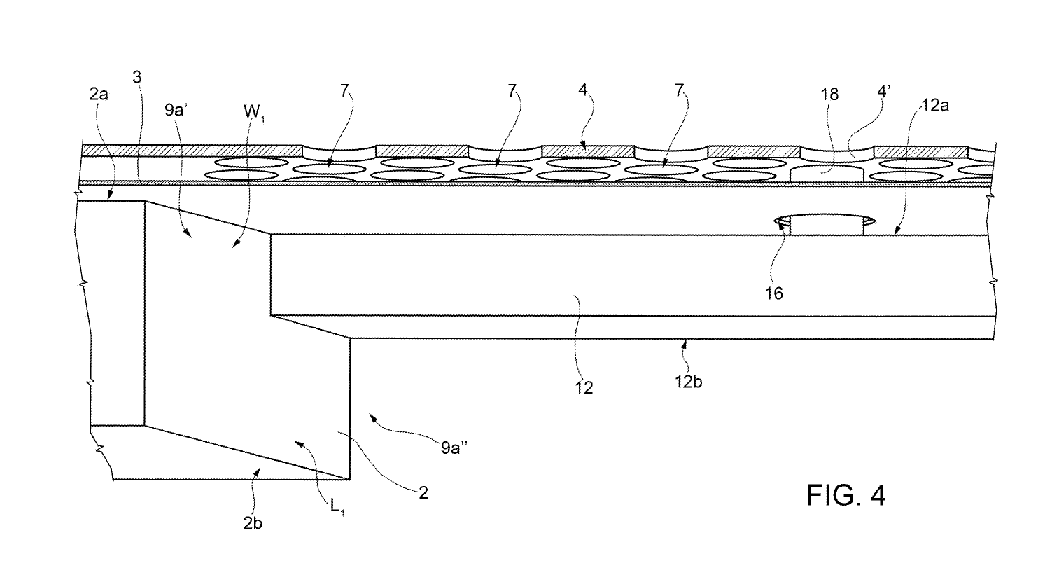

With reference to FIGS. 3, 4 and 5, an embodiment of a micromechanical detection structure according to the present solution, designated by 10, is now described, referring just to the differences with respect to the detection structure 1 illustrated in FIGS. 1 and 2. Parts of the detection structure 10 already described previously are designated by the same references indicating they have the same structure and perform the same function and thus are not discussed again in the interest of brevity.

One aspect of this embodiment envisages, as described in patent application TO2013A000225 filed on Mar. 21, 2013 in the name of the present Applicant, filed in the U.S. on Mar. 20, 2014 with title “Microelectromechanical Sensing Structure for a Capacitive Acoustic Transducer Including an Element Limiting the Oscillations of a Membrane, and Manufacturing Method Thereof,” and having U.S. patent application Ser. No. 14/220,985, incorporated herein by reference, provision of a stopper element 12, underneath the membrane 3 such as to limit the displacements thereof in the direction of the substrate 2.

The stopper element 12 is made of semiconductor material; in particular, it forms an integral part of the substrate 2, from which it is obtained by chemical etching during the manufacturing process (during the same etching steps that also lead to definition of the first cavity 9a, in particular the first cavity portion 9a′).

The stopper element 12 has, in this embodiment, the conformation of an elongated beam, which extends within the first cavity portion 9a′ between the first and second front wall portions W₁, W₂ of the front portion of the substrate 2, parallel to the front surface 2a of the same substrate 2. The stopper element 12 is moreover parallel to the first and second surfaces 3a, 3b of the membrane 3, when the same membrane 3 is in a resting condition, i.e., in an undeformed state.

In particular, in the embodiment illustrated, the stopper element 12 has the shape of a parallelepipedal beam.

The stopper element 12 has a top surface 12a, facing the membrane 3, and a bottom surface 12b, facing the second cavity portion 9a″ of the first cavity 9a.

In the embodiment illustrated, the top surface 12a is coplanar to the front surface 2a of the substrate 2, and moreover the stopper element 12 has a thickness, measured in the vertical direction z orthogonal to the horizontal plane xy, equal to the thickness of the front portion of the substrate 2 (and hence equal to the extension in the vertical direction z of the first and second wall portions W₁, W₂).

In greater detail, the top surface 12a and the bottom surface 12b of the stopper element 12 have an area A such that, if S is the area of any cross section of the first cavity portion 9a′ parallel to the horizontal plane xy, the following relation applies:

A≦0.3·S

The above condition may be such that the presence of the stopper element 12 does not jeopardize the frequency response of the detection structure 10.

Moreover, in a condition at rest, the stopper element 12 is separated from the first surface 3a of the membrane 3 by a distance d such that, in the presence of deformations of a large extent, a central portion of the membrane 3 bears upon the stopper element 12; instead, in normal operating conditions, during detection of incident pressure waves, the membrane 3 is free to oscillate, without coming into contact with the same stopper element 12.

In greater detail, the distance d satisfies the relation:

d=k·h

where h is the thickness of the membrane 3, in the vertical direction z, and k is a constant of proportionality ranging, for example, between 2 and 4 (the thickness h is evidently the smallest of the three dimensions of the membrane 3 in the xyz Cartesian space).

According to a particular aspect of the present embodiment, the detection structure 10 further comprises at least one second plate anchorage 18, which mechanically connects, and constrains, a central portion 4′ of the rigid plate 4 to the stopper element 12.

In particular, the second plate anchorage 18 is defined by a vertical pillar, which extends vertically from the rigid plate 4 (in particular, from the second plate layer 4b, joined thereto) to the top surface 12a of the stopper element 12. Moreover, the second plate anchorage 18 is made, at least in part, of the same material as that of the rigid plate 4.

The membrane 3 thus has at least a further through opening 16, set centrally, in such a way as to be engaged by the aforesaid second plate anchorage 18. In other words, the second plate anchorage 18 traverses the through opening 16 in the membrane 3 in the vertical direction, so as to reach the underlying stopper element 12.

For example, both the second plate anchorage 18 and the further through opening 16, have a circular cross section in the horizontal plane xy.

In the embodiment illustrated, the second plate anchorage 18 contacts the stopper element 12 in a point that divides the stopper element 12 itself into two substantially specular halves, having substantially the same longitudinal extension.

The presence of the second plate anchorage 18, set at the central portion 4′ of the rigid plate 4, where greater mechanical stresses originate during operation due to impact with the membrane 3, hence enables to greatly limit any possible damage to the same rigid plate 4. In fact, the second plate anchorage 18 limits the displacements and deformations of the rigid plate 4, around the central portion 4′, as compared to traditional solutions.

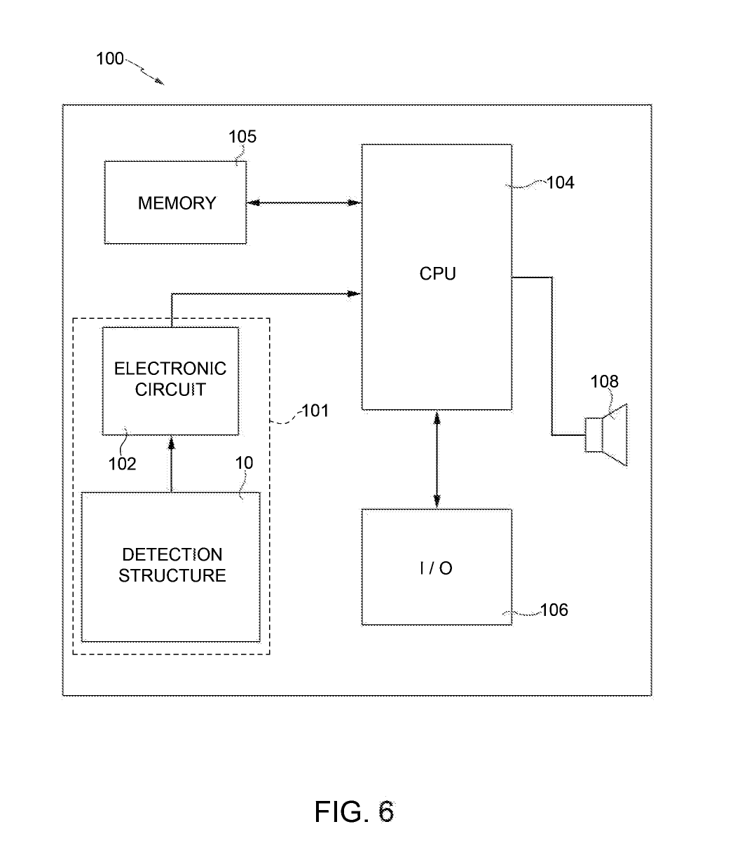

FIG. 6 shows an electronic device 100 that uses one or more MEMS acoustic transducers 101 (just one MEMS acoustic transducer 101 is illustrated in the figure), each comprising a detection structure 10 and a corresponding electronic circuit 102 for processing the transduced electrical signals.

The electronic device 100 comprises, in addition to the MEMS acoustic transducer 101, a microprocessor (CPU) 104, a memory block 105, connected to the microprocessor 104, and an input/output interface 106, for example including a keypad and a display, which is also connected to the microprocessor 104. Although not shown, it is to be appreciated that the electronic device 60 includes a power source, such as a battery.

The MEMS acoustic transducer 101 communicates with the microprocessor 104 via the electronic circuit 102. Moreover, a speaker 108, for generating sounds on an audio output (not shown) of the electronic device 100, may be present.

The electronic device 100 is preferably a mobile communication device, such as for example a mobile phone, a personal digital assistant (PDA), a notebook, but also a voice recorder, or an audio-file player with voice recording capacity. As an alternative, the electronic device 100 may be a hydrophone, which is able to work under water. The electronic device 100 may be a wearable device, including a hearing-aid device.

The advantages of the solution described are clear from the foregoing discussion.

It is in any case once again emphasized that the presence of the second anchorage element 18 for the rigid plate 4, preferably arranged at a central position, enables limitation of its deformations, which could cause even breaking in the case of considerable movements of the membrane 3 (for example, in the case of a free-fall condition).

Moreover, the process for manufacturing the detection structure 10 does not specify any additional process steps as compared to known solutions, using in fact the same process steps with different conformations of the lithographic and chemical-etching masks that lead to definition of the various layers and levels of the detection structure 10.

Finally, it is clear that modifications and variations may be made to what is described and illustrated herein, without thereby departing from the scope of the present disclosure.

In particular, it is evident that also further anchorage elements may be envisaged for connecting the rigid plate 4 to the stopper element 12, in addition to the second plate anchorage 18, suitably arranged to further reduce the deformations of the same rigid plate 4. In this case, further corresponding openings traversing the membrane 3 may be provided, such as to be engaged by respective further anchorage elements.

Also the conformation of the anchorage elements, and in particular of the second plate anchorage 18, may differ from the one illustrated. For example, the second plate anchorage 18 may have a square or rectangular, or generically polygonal, cross section in the horizontal plane xy, instead of being circular.

Moreover, the position of the second plate anchorage 18 may differ from the central arrangement previously illustrated, it being more or less displaced in the horizontal plane xy. In general, this position advantageously corresponds to the position of maximum deformation for the membrane 3.

Also the stopper element 12 may have a different conformation or arrangement within the first cavity 9a. For example, the stopper element 12 may have a thickness equal to the thickness of the entire substrate 2, reaching in this case the back surface 2b of the same substrate 2. In this case, the stopper element 12 extends, not only between the first and second wall portions W₁, W₂, but also between the first and second wall portions L₁, L₂.

In addition, the layout of the rigid plate 4 may have different conformations, according to design specifications.

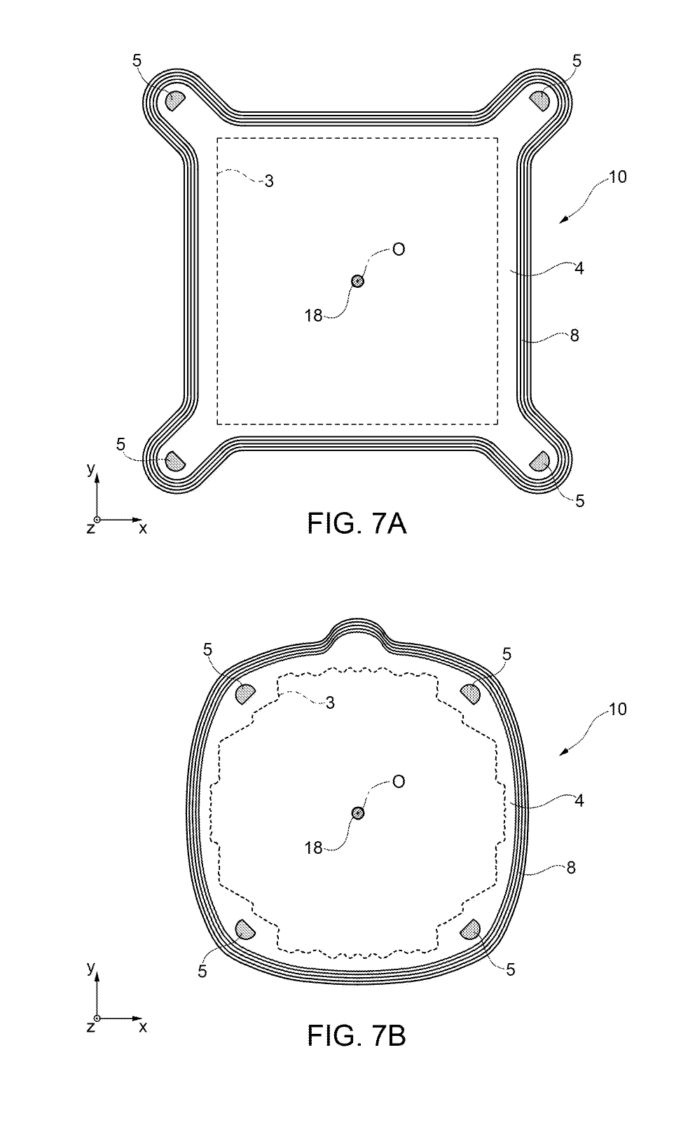

For example, the schematic plan view of FIG. 7a represents a substantially square conformation for the rigid plate 4, which has four prolongations diagonally extending from the corners of the square, in the proximity of which the membrane anchorages 5 are set. The membrane 3, the general layout of which is represented with a dashed line, also has a substantially square conformation. In this solution, the first plate anchorages 8 define a closed perimeter around the membrane 3 and the rigid plate 4.

The schematic plan view of FIG. 7b, shows, instead, a substantially circular conformation of the rigid plate 4 and of the membrane 3. Once again, the membrane anchorages 5 are set at the vertices of an imaginary square in which the rigid plate 4 is inscribed. Also in this solution the first plate anchorages 8 define a closed perimeter around the membrane 3 and the rigid plate 4.

In many embodiments, the second plate anchorage 18 is in any case set at the center with respect to the perimeter of the rigid plate 4 and of the membrane 3, at a center of symmetry O of the entire detection structure 10 (considered in the horizontal plane xy).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A micromechanical structure for a MEMS capacitive acoustic transducer, comprising:
a semiconductor substrate;
a rigid electrode coupled to said substrate;
a membrane having a first surface and a second surface, the second surface facing the rigid electrode, the membrane coupled to said substrate and configured to deform in response to acoustic pressure, the membrane being arranged between the substrate and the rigid electrode;
a first chamber and a second chamber, the first chamber being delimited at least in part by a first wall portion and a second wall portion formed at least in part by the substrate and the first surface of the membrane, and the second chamber being delimited at least in part by the rigid electrode and the second surface of the membrane;
a stopper element coupled between said first and second wall portions and configured to limit deformations of the membrane above a threshold; and
an electrode-anchorage element that couples said rigid electrode to said stopper element.

2. The structure according to claim 1, wherein said membrane has a through opening and the electrode-anchorage element extends through the through opening.

3. The structure according to claim 2, wherein the membrane is arranged between the stopper element and the rigid electrode, and wherein the electrode-anchorage element extends through said through opening from the stopper element to the rigid electrode.

4. The structure according to claim 1, wherein the electrode-anchorage element is coupled to the rigid electrode at a central position of the rigid electrode.

5. The structure according to claim 4, wherein said central position includes a center of symmetry of said rigid electrode in a plane that is parallel to a surface of said substrate.

6. The structure according to claim 1, wherein at least a portion of the electrode-anchorage element is made of the same material as that of the rigid electrode.

7. The structure according to claim 1 further comprising:
electrode anchorages that couple the rigid electrode to the substrate ; and
membrane anchorages that couple the membrane to the substrate .

8. The structure according to claim 7, wherein:
the rigid electrode has a polygonal shape in a plane parallel to a surface of said substrate;
the membrane anchorages are set at vertices of said polygonal shape; and
the electrode-anchorage element is located in a central portion of the polygonal shape.

9. The structure according to claim 1, wherein:
the first and second wall portions delimit a first portion of the first chamber and are defined by a first portion of the substrate proximate a first surface that faces, at least in part, the membrane; and
the first chamber has a second portion in fluid communication with the first portion and defined by a second portion of the substrate proximate a second surface that is vertically opposite to the first surface.

10. The structure according to claim 1, wherein the stopper element has a surface that is substantially parallel to a surface of the membrane when the membrane is in a condition of rest.

11. The structure according to claim 10, wherein the stopper element is so arranged that:
in the presence of external stresses within a first range of amplitudes, a portion of the membrane bears upon the stopper element; and
in the presence of external stresses within a second range of amplitudes, the same portion of the membrane is free to oscillate.

12. The structure according to claim 1, wherein the stopper element is made of semiconductor material.

13. An acoustic transducer comprising:
a micromechanical detection structure
a sensing capacitor including:
a semiconductor substrate;
a rigid electrode coupled to said substrate;
a membrane having a first surface and a second surface, the second surface facing the rigid electrode, the membrane coupled to said substrate and configured to deform in response to acoustic pressure, the membrane being arranged between the substrate and the rigid electrode;
a stopper element coupled to the substrate and facing the first surface of the membrane, the stopper element configured to limit deformations of the membrane above a threshold; and
an electrode-anchorage element coupling said rigid electrode to said stopper element; and
an electronic circuit operatively coupled to the micromechanical detection structure.

14. The acoustic transducer according to claim 13, wherein the electrode-anchorage element is coupled to a center portion of the rigid electrode.

15. The acoustic transducer according to claim 13, wherein the substrate includes an opening that forms a first chamber, the stopper element being a portion of the substrate that extends in the first chamber at a distance from the first surface of the membrane.

16. The acoustic transducer according to claim 13, wherein the membrane includes a through hole, and the electrode-anchorage element extends the through hole of the membrane.

17. A method comprising:
coupling a rigid electrode to a first surface of a semiconductor substrate;
forming a membrane that faces the rigid electrode and is coupled to said substrate, the membrane being configured to undergo deformation in the presence of incident acoustic pressure waves, the membrane arranged between the substrate and the rigid electrode and having a first surface and a second surface in fluid communication, respectively, with a first chamber and a second chamber, the first chamber being delimited at least in part by a first wall portion and by a second wall portion of the substrate, and the second chamber being delimited at least in part by the rigid electrode;
forming a stopper element coupled between said first and second wall portions and configured to limit deformations of the membrane that are above a threshold; and
forming at least one electrode-anchorage element that couples said rigid electrode to said stopper element.

18. The method according to claim 17, comprising forming electrode anchorages that couple the rigid electrode to the substrate; and
wherein forming at least one electrode-anchorage element is performed at least in part while forming the electrode anchorages.

19. The method according to claim 17, comprising defining the first chamber in a surface portion of the substrate by chemical etching; and
wherein forming the stopper element is performed at least in part while defining the first chamber.

20. An electronic device comprising:
an acoustic transducer including:
a sensing capacitor including:
a semiconductor substrate;
a rigid electrode coupled to said substrate;
a membrane having a first surface and a second surface, the second surface facing the rigid electrode, the membrane coupled to said substrate and configured to deform in response to acoustic pressure, the membrane being arranged between the substrate and the rigid electrode;
a stopper element coupled to the substrate and facing the first surface of the membrane, the stopper element configured to limit deformations of the membrane above a threshold; and
an electrode-anchorage element coupling said rigid electrode to said stopper element; and
an electronic circuit operatively coupled to the micromechanical detection structure.

21. The electronic device according to claim 20, wherein the electronic device is at least one of a mobile phone, a personal digital assistant, a notebook, a voice recorder, and an audio-file player with voice recording capacity.
